(19) United States
(12) Patent Application Publication
(10) Pub. No.: US 2002/0089377 A1
(43) Pub. Date: Jul. 11, 2002

(54) Constant transconductance differential amplifier

(76) Inventor: Jong-Tae Hwang, Pucheon-city (KR)

Correspondence Address: MARSHALL, O'TOOLE, GERSTEIN, MURRAY & BORUN, 6300 SEARS TOWER, 233 SOUTH WACKER DRIVE, CHICAGO, IL, 60606-6402, US

(21) Appl. No.: 10/000,418

(22) Filed: Nov. 2, 2001

(30) Foreign Application Priority Data
Nov. 6, 2000 (KR) 2000-65568

(51) Int. Cl. H03F 3/45

(52) U.S. Cl. 330/252; 330/253

(57) ABSTRACT

A differential amplifier includes a first differential amplifying unit for generating a difference between first and second output currents in proportion to a difference between first and second input voltages and a second differential amplifying unit for generating a difference between third and fourth output currents in proportion to a difference between third and fourth input voltages. The differential amplifier also includes a first level shifter for maintaining a constant difference in an offset voltage between the first input voltage and the third input voltage and a second level shifter for maintaining a constant difference in offset voltage between the second input voltage and the fourth input voltage. Additionally, the differential amplifier includes a current switch connected between the first and second differential amplifying units.

### BACKGROUND OF THE INVENTION

1. Field of the Invention

The invention relates generally to differential amplifiers and, more specifically, the invention relates to a differential amplifier that maintains a constant transconductance for input voltages ranging between the minimum and maximum supply voltages of the amplifier and over the entire common-mode input range of the amplifier.

2. Description of the Related Technology

Differential amplifiers are commonly employed in electronic devices that use analog circuits. In addition to a variety of discrete circuit applications, differential amplifiers are also used in many integrated devices such as, for example, operational amplifiers, which are a fundamental building block in many analog circuits and devices. The growing demand for mobile or portable electronic equipment or devices has increased the need to produce simple, lightweight, energy-efficient electronic equipment, which has resulted in an increased demand for low-power operational amplifiers.

Generally speaking, to reduce the power consumption of an operational amplifier, the operational amplifier must be operated at relatively low supply voltages. Unfortunately, as the supply voltage is reduced, the useful dynamic input range and output range of the operational amplifier is reduced. In general, the operating range of the input terminals of an operational amplifier depends on the input stage configuration of the operational amplifier, which is typically a differential amplifier. As is well known, the operating range or dynamic range of the input terminals of a differential amplifier is commonly referred to as a common-mode input range (CMR). In the case of an operational amplifier buffer circuit such as, for example, a voltage follower, the CMR of the operational amplifier determines the dynamic range of the buffer inputs. A differential amplifier that provides a CMR substantially equal to the voltage drop across the supply terminals of the differential amplifier is commonly referred to as a rail-to-rail differential amplifier.

Another important differential amplifier characteristic is the transconductance (gm) of the amplifier input terminals, which represents the ratio of differential amplifier output current variation to differential input voltage variation. The gm of a differential amplifier used within an operational amplifier largely determines the useful bandwidth of the operational amplifier and the total harmonic distortion (THD) produced by the operational amplifier. Ideally, the differential amplifier input stage of an operational amplifier provides rail-to-rail operation and has a constant gm value over the entire CMR of the operational amplifier.

FIG. 2, discussed in greater detail below, illustrates a conventional differential amplifier that uses a combination of a differential amplifying unit having N-type elements (e.g., NPN devices, NMOS devices, etc.) and a differential amplifying unit having P-type elements (e.g., PNP devices, PMOS devices, etc.). If the input terminals of the differential amplifier shown in FIG. 2 operate simultaneously or independently, the differential amplifier may provide a substantially constant gm by varying the bias current Ib of an independent current source. Because the differential amplifier shown in FIG. 2 has four current outputs, additional circuitry is required to appropriately combine the four output currents to have a desired output characteristic. When such additional output conditioning circuitry is implemented using metal oxide semiconductors (MOSs), a difference in the carrier mobility characteristics of NMOS and PMOS devices results in a different in gm in NMOS and PMOS devices that have the same current capacity or rating and which are of the same physical size. Thus, producing NMOS and PMOS devices that have the same gm requires relatively precise control of the physical sizes of the semiconductor structures that make up these devices. Furthermore, carrier mobility varies with the process, which makes it difficult to realize a substantially constant gm over the whole rail-to-rail range of a differential amplifier that uses NMOS and PMOS devices.

FIG. 1 is an exemplary schematic diagram of a conventional differential amplifier. As shown in FIG. 1, the conventional differential amplifier may be composed of NPN bipolar transistors Q1, Q2 and Q3, all of which may be connected as shown. In operation, a difference between the input voltages Vin+ and Vin− results in a difference between the output currents I1 and I2. The ratio of current variation to voltage difference is the gm of the amplifier as shown in Equation 1 below.

$$gm = \frac{\partial ( I1 - I2 )}{\partial [ ( Vin + ) - ( Vin - ) ]} \qquad [ Equation 1 ]$$

For an NPN differential amplifier, such as that shown in FIG. 1, the gm is dependent on the bias current flowing through the transistors as shown in Equation 2 below.

$$gm = \frac{Ib}{{V}_{T}} = \frac{Ib}{\frac{kT}{q}} \qquad [ Equation 2 ]$$

In Equation 2, Ib represents a bias current, k represents Boltzmann's constant, T represents absolute temperature and q represents the charge of an electron. From Equation 2 it can be seen that the gm is directly proportional to the bias current Ib. Ideally, the bias current Ib remains constant so that the gm does not vary. However, in practice the bias current Ib varies and, as a result, gm varies when the common-mode input voltage (VCM) at the input terminals of Q1 and Q2 falls below the sum of the base-emitter voltages (Vbes) of the transistors Q1 or Q2. In particular, when the VCM falls below the sum of the Vbes, the collector-emitter voltage (Vce) of the transistor Q3 falls below a minimum level and causes the transistor Q3 to operate in its saturation range. When the transistor Q3 saturates, the bias current Ib is reduced, which causes the gm of the amplifier to be reduced.

FIG. 2 is a schematic diagram of a known complementary differential amplifier configuration that may be used to provide a substantially constant gm over a wider range of input voltages than that provided by the amplifier circuit shown in FIG. 1. As shown in FIG. 2, the complementary amplifier configuration combines a PNP differential amplifying unit with a NPN differential amplifying unit. The gm of the complementary amplifier shown in FIG. 2 may be expressed as shown in Equation 3 below.

$$gm = \frac{\partial [ ( I1 - I2 ) + ( I3 - I4 ) ]}{\partial [ ( Vin + ) - ( Vin - ) ]} \qquad [ Equation 3 ]$$

The NPN differential amplifying unit operates for the upper portion of the common-mode input voltage range and the PNP differential amplifying unit operates for the lower portion of the common-mode input voltage range. Thus, the combined operation of the NPN and PNP differential amplifying units enables rail-to-rail operation of the amplifier shown in FIG. 2. Unfortunately, as discussed in connection with FIG. 3 below, while the differential amplifier shown in FIG. 2 provides rail-to-rail operation, this differential amplifier does not provide a substantially constant gm over the whole CMR of the amplifier.

FIG. 3 is a graphical representation that illustrates gm variations of the NPN and PNP differential amplifying units used in the circuit of FIG. 2 as function of VCM. As shown in FIG. 3, the differential amplifier of FIG. 2 may operate over the whole CMR range but the gm varies by 100%. When a differential amplifier such as that shown in FIG. 2 is used within an operational amplifier, the relatively large variation of gm with VCM results in a significant variation of the unit y gain bandwidth of the operational amplifier and increases the THD of the operational amplifier.

The differential amplifier circuit shown in FIG. 2 uses an additional circuit to vary the bias currents as VCM changes so that the total gm of the differential amplifier remains substantially constant over the entire CMR. In particular, when the NPN and PNP differential amplifying units of the circuit shown in FIG. 2 operate simultaneously, the Ib value is reduced to 50% of its maximum value. Consequently, the currents that flow to I1, I2, I3 and I4 as a function of VCM are: I1=I2=Ib/2 and I3=I4=0 when only the NPN input terminals operate; I3=I4=Ib/2 and I1=I2=0 when only the PNP input terminals operate; and I1=I2=I3=I4=Ib/4 when both the NPN and PNP input terminals operate. Because the circuit shown in FIG. 2 has four current outputs, any subsequent circuit, next stage or output conditioning circuit must appropriately combine the four current outputs to produce a useful output voltage.

The practical difficulties in implementing a circuit such as that shown in FIG. 2 becomes even more serious in the case where metal oxide semiconductor field effect transistors (MOSFETs) are used instead of bipolar transistors. Unlike a bipolar transistor, a MOSFET has a gm that may be expressed as shown in Equation 4 below.

$$gm = \sqrt{2 I μ {C}_{ox} \frac{W}{L}} \qquad [ Equation 4 ]$$

In Equation 4, I represents the drain current of the MOSFET, μ represents the carrier mobility, Cₒₓ represents the unit capacity of the gate of the MOSFET, W/L represents the width/length of a channel.

The gm of a rail-to-rail differential amplifier that uses a complementary pairs of NMOS and PMOS differential amplifying units is the sum of the gms of the NMOS and PMOS units as shown in Equation 5 below.

$$gm = \sqrt{2 {I}_{N} {μ}_{N} {{C}_{ox} ( \frac{W}{L} )}_{N}} + \sqrt{2 {I}_{P} {μ}_{P} {{C}_{ox} ( \frac{W}{L} )}_{P}} \qquad [ Equation 5 ]$$

In Equation 5, the subscript N identifies the NMOS unit contribution to the overall gm of the complementary unit and the subscript P represents the PMOS unit contribution.

If the NMOS unit is the same as the PMOS unit except for the current I, i.e.,

$${μ}_{N} {( {C}_{o x} ( \frac{W}{L} ) )}_{N} = {μ}_{P} {( {C}_{o x} ( \frac{W}{L} ) )}_{P} ,$$

the bias current must be reduced to one-quarter of its maximum value in the VCM operating range where the PMOS and NMOS units operate simultaneously to have a constant gm value over the entire rail-to-rail range of the differential amplifier. Consequently, the currents I1, I2, I3 and I4 are: I1=I2=Ib/2 and I3=I4=0 when only the NMOS input terminals operate; I3=I4=Ib/2 and I1=I2=0 when only the PMOS input terminals operate; and I1=I2=I3=I4=Ib/8 when both the NMOS and PMOS input terminals operate.

However, in practice, achieving a constant gm in a complementary MOSFET-based differential amplifier having a topology such as that shown in FIG. 2 is very difficult. In particular, a difference in the carrier mobilities of the NMOS and PMOS devices requires accurate control the physical sizes of the two structures making up the NMOS and PMOS devices. This need is further complicated by the fact that the carrier mobilities within NMOS and PMOS devices are greatly affected by the fabrication process and the fact that carrier mobility characteristics vary over the surface of a given semiconductor wafer.

### SUMMARY OF THE INVENTION

A differential amplifier may include a first differential amplifying unit for generating a difference between first and second output currents in proportion to a difference between first and second input voltages and a second differential amplifying unit for generating a difference between third and fourth output currents in proportion to a difference between third and fourth input voltages. The differential amplifier may also include a first level shifter for maintaining a constant difference in an offset voltage between the first input voltage and the third input voltage and a second level shifter for maintaining a constant difference in offset voltage between the second input voltage and the fourth input voltage.

Additionally, the differential amplifier may include a current switch connected between the first and second differential amplifying units. The current switch may be adapted to divide a common-mode input range associated with the first and second differential amplifying units.

Still further, the differential amplifier may include a first constant current source for maintaining a constant sum of the first and second output currents of the first differential amplifying unit and a constant sum of the third and fourth output currents of the second differential amplifying unit. A first output current terminal of the first differential amplifying unit may be connected to a second output current terminal of the second differential amplifying unit to form a third output current terminal, and a fourth output current terminal of the first differential amplifying unit may be connected to a fifth output current terminal of the second differential amplifying unit to form a sixth output current terminal.

### BRIEF DESCRIPTION OF THE DRAWINGS

FIG. 1 is an exemplary schematic diagram of a conventional differential amplifier;

FIG. 2 is a schematic diagram of a known complementary differential amplifier configuration;

FIG. 3 is a graphical representation that illustrates gm variations of the NPN and PNP differential amplifying units used in the circuit of FIG. 2 as function of VCM;

FIG. 4 is an exemplary schematic diagram of a constant transconductance differential amplifier;

FIG. 5a is an exemplary graphical representation of the gm as a function of VCM for a first differential amplifying unit used within the constant transconductance differential amplifier shown in FIG. 4;

FIG. 5b is an exemplary graphical representation of the gm as a function of VCM for a second differential amplifying unit used within the constant transconductance differential amplifier shown in FIG. 4;

FIG. 5c is an exemplary graphical representation of the total gm for the constant transconductance differential amplifier shown in FIG. 4;

FIG. 6 is an exemplary schematic diagram of another constant transconductance differential amplifier;

FIG. 7a is an exemplary graphical representation of the gm of first and second differential amplifying units in a strong inversion range in the constant transconductance differential amplifier shown in FIG. 6; and

FIG. 7b is an exemplary graphical representation of the gm of the first and second differential amplifying units in a weak inversion range in the constant transconductance differential amplifier shown in FIG. 6.

### DETAILED DESCRIPTION OF THE PREFERRED EMBODIMENTS

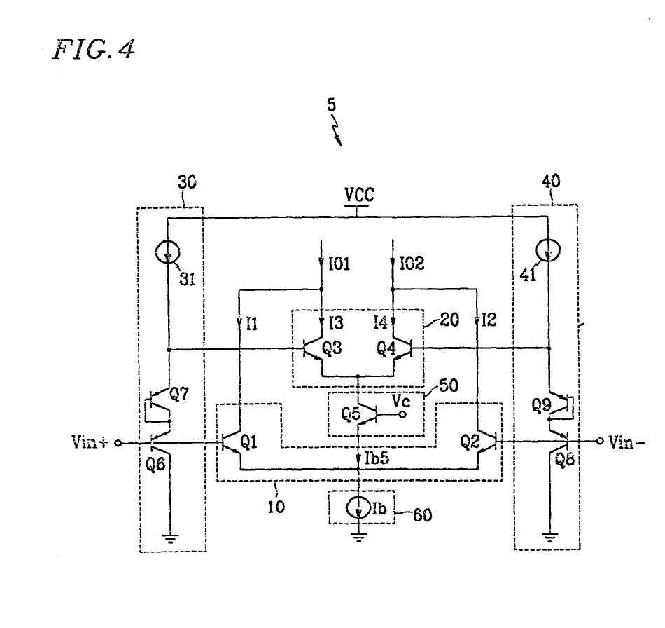

FIG. 4 is an exemplary schematic diagram of a constant transconductance differential amplifier 5. As shown in FIG. 4, the differential amplifier 5 includes a first differential amplifying unit 10, a second differential amplifying unit 20, a first level shifter 30, a second level shifter 40, a current switch 50 and a first constant current source 60, all of which may be connected as shown in FIG. 4. The first differential amplifying unit 10 includes first and second transistors Q1 and Q2 and generates a difference between first and second output currents I1 and I2 in proportion to a difference between first and second input voltages Vin+ and Vin−. Likewise, the second differential amplifying unit 20 includes third and fourth transistors Q3 and Q4 and generates a difference between third and fourth output currents I3 and I4 in proportion to a difference between the first and second input voltages Vin+ and Vin−. In contrast to known complementary differential amplifiers, such that shown in FIG. 2, the amplifying units 10 and 20 of the differential amplifier 5 shown in FIG. 4 include all N-type or all P-type elements.

The first and second level shifters 30 and 40 maintain a constant difference in offset voltage between the base terminals of the transistors Q1 and Q2 and the base terminals of the transistors Q3 and Q4 so that the second differential amplifying unit 20 operates normally when the first differential amplifying unit 10 has a low gm due to a low VCM. Preferably, but not necessarily, the first level shifter 30 includes transistors Q6 and Q7 and a second constant current source 31. Similarly, the second level shifter 40 includes transistors Q8 and Q9 and a third constant current source 41.

The current switch 50 includes a single transistor Q5 and divides the VCM range so that the first and second differential amplifying units 10 and 20 operate when a predetermined reference voltage Vc is applied to the base of the transistor Q5. As shown, the first constant current source 60 may be configured using a conventional current source topology including, for example, a transistor, or may use any other suitable current source circuit topology. In any case, the first current source 60 maintains the sum of output currents Io1 and Io2 at a constant value.

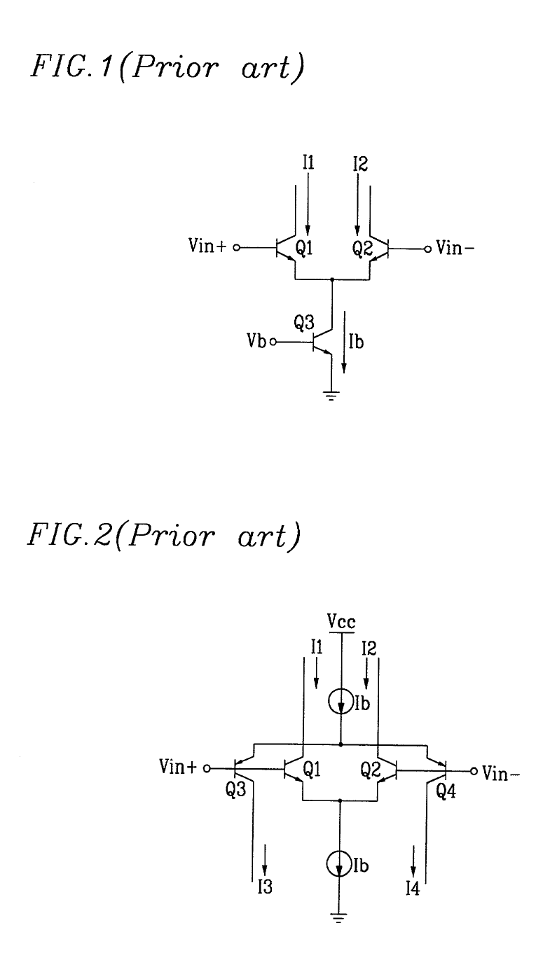

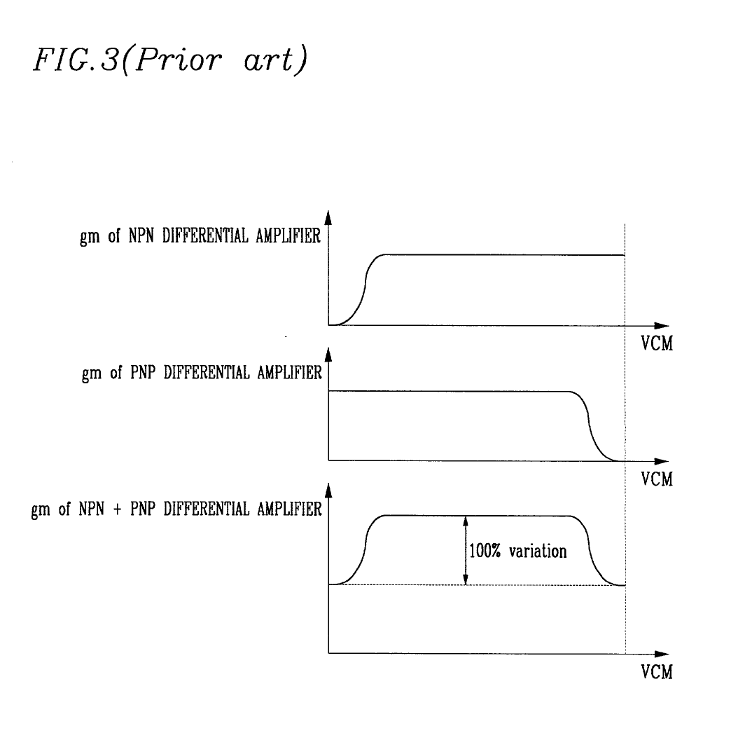

The first differential amplifying unit 10 and the first constant current source 60 constitute a differential amplifier such as that shown in FIG. 1. Thus, to provide a desired gm value for the first differential amplifying unit 10, the VCM must be greater than the sum of the base-emitter voltages (i.e., Vbes) of the transistors Q1 or Q2 and the minimum collector-emitter voltage Vce of the transistor constituting the first constant current source 60.

To produce a desired, constant gm, despite a low VCM (i.e., over the entire CMR), the differential amplifier 5 uses the first and second level shifters 30 and 40 and the transistors Q3 and Q4.

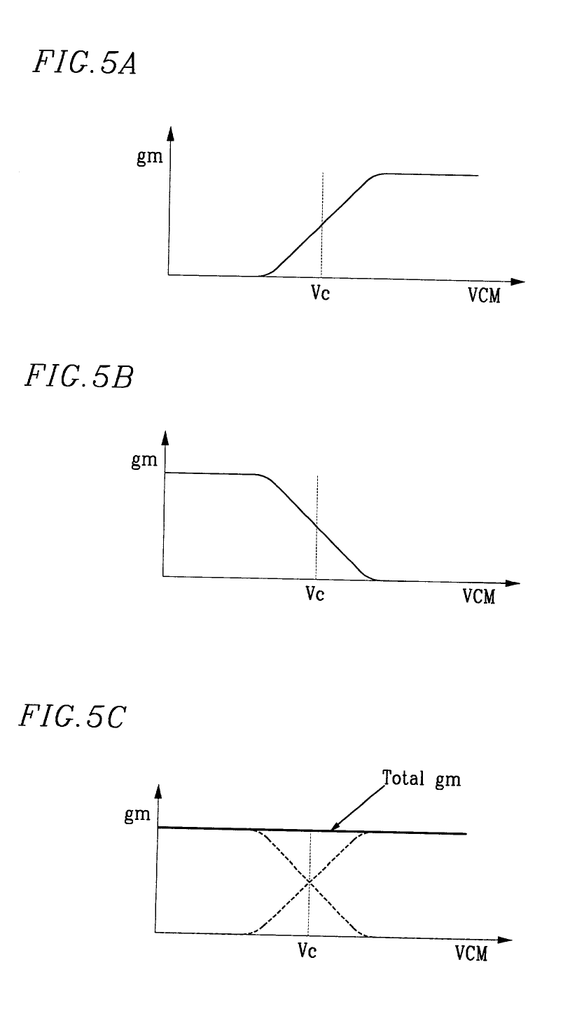

For clarity, the following description of operation of the differential amplifier 5 considers the VCM range in three distinct intervals. In an interval where the VCM is greater than Vc, a base-emitter voltage Vbe of the transistor Q5 is not applied to the transistor Q5, which turns the transistor Q5 of the current switch 50 off. With the current switch 50 off, the transistors Q3 and Q4 are turned off, which turns off the second differential amplifying unit 20. The gm characteristic during this interval may be expressed by Equation 2 above and is graphically represented in FIG. 5a.

In an interval where the VCM is less than Vc, the base-emitter voltage Vbe of the transistor Q5 turns on the transistor Q5 and turns off the transistors Q1 and Q2. This stops the operation of (i.e., turns off) the first differential amplifying unit 10 and enables the operation of (i.e., turns on) the second differential amplifying unit 20.

To enable the second differential amplifying unit 20 to operate normally while the VCM is relatively low, a predetermined offset voltage may be added to the first and second input voltages Vin+ and Vin− via the bases of the transistors Q3 and Q4. This offset voltage causes the gm to be the same as in the case where VCM>Vc because the transistors Q1, Q2, Q3 and Q4 have the same characteristics and the current Ib is constant. The gm can be expressed by Equation 2 and may have a characteristic such as that shown in FIG. 5b.

In an intermediate interval between the two intervals described above, the transistor Q5 is not completely turned on or off and current flows through the transistors Q1, Q2, Q3 and Q4. In this case, when the current flowing to the transistor Q5 is defined to be Ib5, the gm of the second differential amplifying unit 20 may be expressed as shown in Equation 6 below.

$$gm = \frac{Ib5}{{V}_{T}} \qquad [ Equation 6 ]$$

Similarly, the gm provided by the transistors Q1 and Q2 may be expressed as shown in Equation 7 below.

$$gm = \frac{Ib - Ib5}{{V}_{T}} \qquad [ Equation 7 ]$$

Because the total gm is the sum of the two gm values, the total gm becomes Ib/V_{T}, which is the same as Equation 2 above. As shown in FIG. 5c, the total gm is constant over the entire range of the VCM.

The second differential amplifying unit 20 can operate when the first and second level shifters 30 and 40 operate, even if VCM is zero volts. Thus, the first and second level shifters 30 and 40 are preferably composed of P-type elements or transistors when the differential amplifying units 10 and 20 use N-type elements or transistors. Because the transistors Q6 and Q8 have a PNP structure, the level shifters 30 and 40 do not interfere with the operation of the amplifying unit 20, even if the base voltage is zero volts. Additionally, because the level shifters 30 and 40 are configured as grounded collector voltage followers, they provide a voltage gain of 1 and do not affect the total gm of the differential amplifier 5 and they exhibit a high-speed operating characteristic.

The transistors Q7 or Q9 may be used to generate a sufficiently high offset voltage. However, the transistors Q7 or Q9 may be replaced with any other circuit element or component that produces a voltage drop such as, for example a resistor, a Zener diode, a MOS device, etc. Preferably, but not necessarily, the element producing the voltage drop provides a low impedance because the use of an element having a large resistance or impedance may reduce the gain of the first and second level shifters 30 and 40 and thereby change the gm value. Additionally, the second and third constant current sources 31 and 41 may be implemented with resistors, which may reduce the gain.

To enable operation of the transistors Q3 and Q4 when the VCM is zero, the offset voltage must be greater than the sum of a base-emitter voltages (Vbes) for operating the transistors Q3 and Q4 and a collector-emitter voltage Vce for operating the transistor Q5 in a saturation range. The collector-emitter voltage Vce is dependent on a reference voltage Vc applied to the base of the transistor Q5. Thus, the reference voltage Vc is preferably as low as possible.

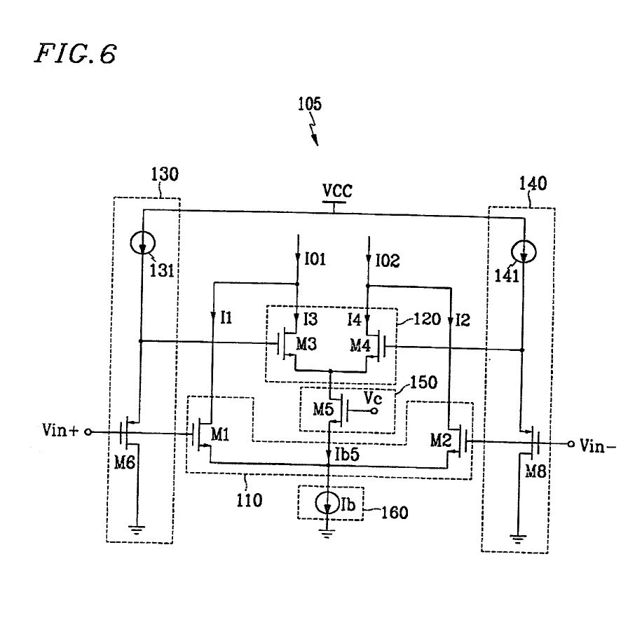

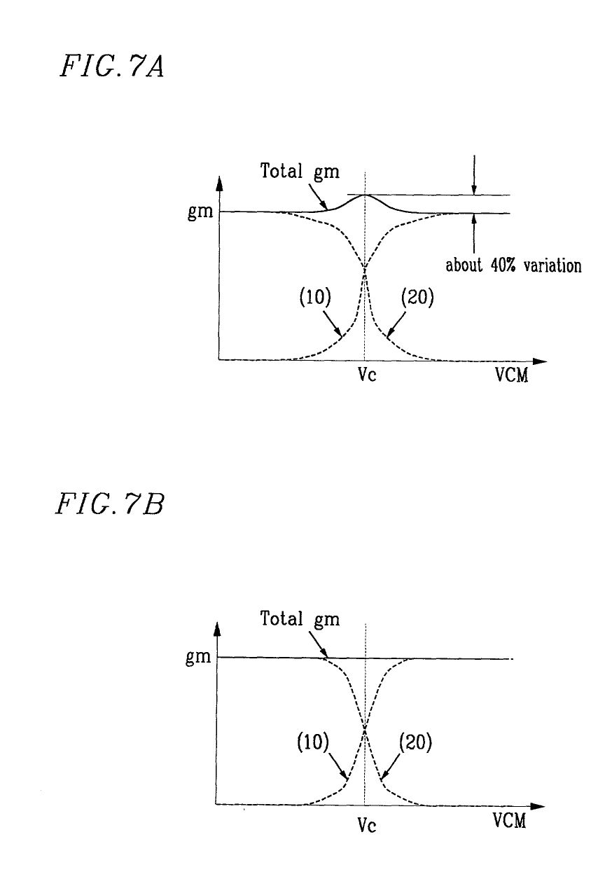

FIG. 6 is an exemplary schematic diagram of another constant transconductance differential amplifier 105. FIGS. 7a and 7b are exemplary graphical representations of the gms of first and second differential amplifying units 110 and 120 in strong and weak inversion ranges, respectively, in the differential amplifier shown in FIG. 6. As shown in FIG. 6, the differential amplifier 105 is implemented using NMOS elements. The amplifier 105 shown in FIG. 6 includes the first amplifying unit 110, the second amplifying unit 120, a first level shifter 130 having a current source 131, a second level shifter 140 having a current source 141, a current switch 150 and a constant current source 160. For clarity, the following description describes the operation of the differential amplifier 105 within three distinct intervals of the VCM range.

In an interval where the VCM is greater than Vc, a gate-source voltage of transistor M5 is not applied to the transistor M5, which turns the transistor M5 off. This stops the operations of (i.e., turns off) transistors M3 and M4 and, thus, the second differential amplifying unit 120 is turned off or becomes inactive. The gm of the amplifying unit 120 can be expressed by Equation 4.

In an interval where the VCM is less than Vc, the gate-source voltage of the transistor M5 is applied to turn the transistor M5 on and the transistors M1 and M2 off. As a result, the first differential amplifying unit 110 is not operated and the operation of the second differential amplifying unit 120 is operated. To enable the second differential amplifying unit 120 to operate normally with a low VCM, a predetermined offset voltage added to first and second input voltages Vin+ and Vin− may be applied to the gates of transistors M3 and M4.

The gm is the same as in the case where VCM>Vc, because the transistors M1, M2, M3 and M4 have the same characteristics and the current Ib is constant. The gm can be expressed by Equation 4.

In an intermediate interval between the two intervals discussed above in connection with FIG. 6, the transistor M5 is not completely turned on or off and current flows through all the transistors M1, M2, M3 and M4. When the currents flowing to the transistors M1, M2, M3 and M4 are all the same, the gm may be expressed as shown in Equation 8 below.

$$gm = \sqrt{2} \cdot \sqrt{2 I μ {C}_{ox} \frac{W}{L}} \approx 1.41 \times \sqrt{2 I μ {C}_{ox} \frac{W}{L}} \qquad [ Equation 8 ]$$

As shown in FIG. 7a, when the VCM approaches Vc, there is a change in the gm by 40%. This variation in gm is approximately equal to the variation of gm typically found in the conventional differential amplifiers that use a combination of NMOS and PMOS elements. Preferably, but not necessarily, the first and second level shifters 130 and 140 include the constant current source 131 and the transistor M6, and the constant current source 141 and the transistor M8, respectively. The gate-source voltage of a MOS element operating in a strong inversion range is a function of the size and the current flowing through the MOS element. Thus, a desired offset voltage may be obtained by controlling the size and the current of the MOS element, which reduces the number of necessary elements.

To overcome the problem that the gm is varied at around the Vc, the MOS elements of the first and second differential amplifying units 110 and 120 are operated in a weak inversion range to have a constant gm over the whole CMR range. The voltage-current relationship of the MOS element in the weak inversion range may be expressed as shown in Equation 9 below.

$$I = μ \cdot {C}_{ox} \cdot \frac{W}{L} \cdot {( \frac{k T}{q} )}^{2} \cdot {ⅇ}^{1.8} \cdot {ⅇ}^{\frac{q ( V g s - V t )}{N \cdot k T}} \qquad [ Equation 9 ]$$

In Equation 9, I represents a source-drain current and Vgs represents a gate-source voltage of the MOS element.

Accordingly, the MOS element in the weak inversion range has a voltage-current relationship that is similar to that of a bipolar transistor, and the gm may be expressed by Equation 10 shown below.

$$gm = \frac{\partial I}{\partial Vgs} = \frac{I}{N \cdot \frac{kT}{q}} \qquad [ Equation 10 ]$$

This second embodiment in which the MOS element is operated in the weak inversion range shows a constant gm similar to that of the bipolar element used in the amplifier shown in FIG. 4, except that a constant N is added, wherein N is a value of about 2 and the gm is about half of the gm of the bipolar element. The variation of gm in this case is shown in FIG. 7b.

An operation of elements in the weak inversion range reduces the power consumption so that the MOS elements of the first and second level shifters 130 and 140 are preferably operated in the weak inversion range to reduce the total power consumption. However, when the transistors M6 and M8 operate in the weak inversion range, the current must be sufficiently low to reduce the gate-source voltage of the MOS element, which makes it difficult to obtain a sufficiently high offset voltage. In this case, it is preferable that the differential amplifier 105 also includes an additional potential difference generating element such as a MOS transistor, a resistor, a diode, or the like.

The forgoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications and variations will be apparent to those skilled in the art.

For example, the differential amplifier described herein may be implemented using P-type semiconductor elements, and the level shifters may be varied as described above. Also, the differential amplifier may be implemented using a junction field effect transistor (JFET) or other three-terminal amplifying elements, and can be implemented with a compound semiconductor element such as, for example, SiGe or GaAs elements.

When the differential amplifier described herein employs a metal semiconductor field effect transistor (MESFET) fabricated by the GaAs process, another level shift circuit different from that used in the embodiments described herein must be used due to a difficulty in manufacturing a complementary element.

The differential amplifier described herein has a differential input unit composed only of N-type or P-type elements that form a circuit having a constant gm over the entire rail-to-rail range. Additionally, the differential amplifier described herein has two current output terminals, as compared to the four current output terminals used with prior complementary differential amplifiers. Furthermore, the constant transconductance differential amplifier described herein is configured to output a constant bias current and eliminates the need for an additional circuit for compensating for the variation of bias current in the next stage of the differential amplifier.

What is claimed is:

1. A differential amplifier comprising:
a first differential amplifying unit for generating a difference between first and second output currents in proportion to a difference between first and second input voltages;
a second differential amplifying unit for generating a difference between third and fourth output currents in proportion to a difference between third and fourth input voltages;
a first level shifter for maintaining a constant difference in an offset voltage between the first input voltage and the third input voltage;
a second level shifter for maintaining a constant difference in offset voltage between the second input voltage and the fourth input voltage;
a current switch connected between the first and second differential amplifying units, wherein the current switch is adapted to divide a common-mode input range associated with the first and second differential amplifying units; and
a first constant current source for maintaining a constant sum of the first and second output currents of the first differential amplifying unit and a constant sum of the third and fourth output currents of the second differential amplifying unit, wherein a first output current terminal of the first differential amplifying unit is connected to a second output current terminal of the second differential amplifying unit to form a third output current terminal, and wherein a fourth output current terminal of the first differential amplifying unit is connected to a fifth output current terminal of the second differential amplifying unit to form a sixth output current terminal.

2. The differential amplifier of claim 1, wherein the first differential amplifying unit has a first three-terminal amplifying element and a second three-terminal amplifying element, wherein each of the first and second three-terminal amplifying elements has a current input terminal, a current output terminal and a control signal supplying terminal, and wherein the current output terminal of the first three-terminal amplifying element is connected to a current output terminal of the second three-terminal amplifying element and to a common terminal of the current switch and the first constant current source.

3. The differential amplifier of claim 2, wherein the second differential amplifying unit has a third three-terminal amplifying element and a fourth three-terminal amplifying element, wherein each of the third and fourth three-terminal amplifying elements has a current input terminal, a current output terminal and a control signal supplying terminal, and wherein the current output terminal of the third three-terminal amplifying element is connected to the current output terminal of the fourth three-terminal amplifying element and to a current input terminal of the current switch.

4. The differential amplifier of claim 3, wherein the first and second three-terminal amplifying elements of the first differential amplifying unit and the third and fourth three-terminal amplifying elements of the second differential amplifying unit are N-type elements.

5. The differential amplifier of claim 3, wherein the first and second three-terminal amplifying elements of the first differential amplifying unit and the third and fourth three-terminal amplifying elements of the second differential amplifying unit are P-type elements.

6. The differential amplifier of claim 3, wherein the current switch comprises a fifth three-terminal amplifying element, wherein a current input terminal of the fifth three-terminal amplifying element is connected to a common terminal of the first and second three-terminal amplifying elements of the first differential amplifying unit, and wherein a current output terminal of the fifth three-terminal amplifying element is connected to a common terminal of the second and fourth three-terminal amplifying elements of the first differential amplifying unit, and wherein a predetermined reference voltage applied to a control signal supplying terminal of the fifth three-terminal amplifying element divides a common-mode input range associated with the first and second differential amplifying units.

7. The differential amplifier of claim 2, wherein the first constant current source is connected to a common terminal of the current switch and the first and second three-terminal amplifying elements, and wherein the first constant current source is adapted to maintain a constant sum of the first and second output currents of the first differential amplifying unit and a constant sum of the third and fourth output currents of the second differential amplifying unit.

8. The differential amplifier of claim 1, wherein the first level shifter comprises:
an input terminal connected to the first input voltage terminal of the first differential amplifying unit;
an output terminal connected to the first input voltage terminal of the second differential amplifying unit; and
a potential difference generating element and a second constant current source that depends on the level of an offset voltage associated with the first input voltage terminals of the first and second differential amplifying units.

9. The differential amplifier of claim 1, wherein the second level shifter comprises:
an input terminal connected to an input voltage terminal of the first differential amplifying unit;
an output terminal connected to an input voltage terminal of the second differential amplifying unit; and
a potential difference generating element and a third constant current source that depends on the level of an offset voltage associated with the input voltage terminals of the first and second differential amplifying units.

10. The differential amplifier of claim 9, wherein the first and second level shifters comprise one of a P-type and an N-type three-terminal amplifying element as the potential difference generating element, and wherein the first and second level shifters are configured as voltage followers.

11. The differential amplifier of claim 9, wherein each of the first and second level shifters comprises:
a P-type three-terminal amplifying element as the potential difference generating element when the first and second differential amplifying units comprise an N-type three-terminal amplifying element; and
an N-type three-terminal amplifying element as the potential difference generating element when the first and second differential amplifying units comprise a P-type three-terminal amplifying element.

12. The differential amplifier of claim 1, wherein the first and second level shifters further comprise one of a resistor, a diode and a three-terminal amplifying element as a potential difference generating element.

13. The differential amplifier of claim 2, wherein each of the three-terminal amplifying elements includes a bipolar transistor.

14. The differential amplifier of claim 3, wherein each of the three-terminal amplifying elements includes a metal oxide semiconductor (MOS) transistor.

15. The differential amplifier of claim 14, wherein a current value of the first constant current source is a subthreshold current value of the MOS transistors of the first and second differential amplifying units so that the MOS transistors of the first and second differential amplifying units operate in a weak inversion range.
